(19) United States
(12) Patent Application Publication
(10) Pub. No.: US 2010/0264428 A1
(43) Pub. Date: Oct. 21, 2010

(54) SILICON BIOSENSOR AND METHOD OF MANUFACTURING THE SAME

(76) Inventors: Chul Huh, Daejeon (KR); Kyung Hyun Kim, Daejeon (KR); Jong Cheol Hong, Daejeon (KR); Hyun Sung Ko, Daejeon (KR); Wan Joong Kim, Gyunggi-do (KR); Gun Yong Sung, Daejeon (KR); Seon Hee Park, Daejeon (KR)

Correspondence Address: LADAS & PARRY LLP, 224 SOUTH MICHIGAN AVENUE, SUITE 1600, CHICAGO, IL, 60604, US

(21) Appl. No.: 12/746,250

(22) PCT Filed: May 21, 2008
(86) PCT No.: PCT/KR2008/002815

§ 371 Date: Jun. 4, 2010

(30) Foreign Application Priority Data
Dec. 10, 2007 (KR) 10-2007-0127881

(51) Int. Cl. H01L 31/12; H01L 21/70

(52) U.S. Cl. 257/84; 438/24; 438/59; 257/E21.532; 257/E33.077

(57) ABSTRACT

A silicon biosensor and a method of manufacturing the same are provided. The silicon biosensor includes: a light emitting layer emitting light according to injected electrons and holes and changing a wavelength of the light depending on whether a biomaterial is absorbed by the light emitting layer; an electron injection layer injecting the electrons into the light emitting layer; and a hole injection layer injecting the holes into the light emitting layer. Accordingly, it is possible to produce low price biosensors in large quantities.

### TECHNICAL FIELD

The present invention relates to a biosensor, and more particularly, to a new type silicon biosensor capable of concurrently performing a function of a light source and a function of a reaction unit based on silicon nano crystal and a method of manufacturing the same.

### BACKGROUND ART

A biosensor is constructed with a bioreceptor and a signal transducer so as to selectively sense a material to be analyzed. An enzyme, an antibody, an antigen, a cell, a DNA, and the like which selectively react on a predetermined material are used as the bioreceptor. Various physical and chemical methods such as an electrochemical method, a fluorescent method, an optical method, a piezoelectric method, and the like are used as a signal transducing method.

The biosensor may be widely applied to environments, foods, the military, industry, a sensor for a research, in addition to a research on genes and a diagnosis of a disease.

In general, a sensing method based on a coloration or fluorescent phenomenon due to an enzyme reaction is widely used as a sensing method used for a diagnosis of a disease.

In addition, as a research on an antigen and an antibody has been developed, a sensing method using an immunoassay by using combination of an antigen and an antibody is actively researched. A practical product for the sensing method has been used.

In a conventional method of detecting a biomaterial, a marking-type biosensor in which a antibody is marked with a radioactive isotope or a fluorescent material, an antigen corresponding to the antibody is detected, an amount of the antigen is recognized based on strength of radioactive rays or fluorescent light emitted from the biosensor has been widely used.

However, in the method of detecting the biomaterial requires an additional procedure of marking the antibody with the fluorescent material. A procedure of preparing a sample is also complex.

Recently, in order to solve the aforementioned problem, optical biosensors such as a surface plasmon biosensor, a total internal reflection ellipsometry biosensor, a waveguide biosensor, and the like are developed as a no-marking biosensor which does not use a marking material such as a fluorescent material.

These optical biosensors are constructed with a light source for generating light, a reaction unit in which a reaction between an antibody and an antigen occurs, and a detection unit for measuring a light signal. A light emitting diode and a laser are used as the light source. A spectrometer is used as a detection unit for measuring the light signal.

In general, in the optical biosensors, the light source for generating light is manufactured by using a gallium arsenide (GaAs) based compound semiconductor thin film and a gallium nitride (GaN) based compound semiconductor thin film.

However, when the light source is manufactured by using the gallium arsenide (GaAs) based compound semiconductor thin film and the gallium nitride (GaN) based compound semiconductor thin film, it is difficult to grow a high quality compound semiconductor thin film on the substrate. The substrate and a gas source for growing the compound semiconductor thin film are expensive.

That is, a manufacturing cost of the light source used for the conventional optical biosensor is expensive.

In addition, since the compound semiconductor thin film used to manufacture the light source applied to the conventional optical biosensor are grown on a no-silicon based substrate, it is difficult to integrate or join the compound semiconductor thin film into silicon electronic elements. Accordingly, it is difficult to produce low price biosensors in large quantities.

Furthermore, when the optical biosensor is constructed with a light source and a spectrometer that is a detection unit, a signal that is output from the detection unit is sensitively changed according to a direction in which light is incident onto a reaction unit in which a reaction between an antibody and an antigen occurs. Accordingly, a complex optical system is needed.

### DISCLOSURE OF INVENTION

### Technical Problem

The present invention provides a silicon biosensor with low manufacturing costs which is easily integrated into silicon elements without an additional light source and an additional optical system and a method of manufacturing the same so as to solve a problem in high manufacturing costs, a problem in that it is difficult to integrate or join a conventional biosensor into silicon electronic elements, and a problem in that the conventional biosensor needs an additional light source and an additional optical system.

### Technical Solution

According to an aspect of the present invention, there is provided a silicon biosensor comprising: a light emitting layer emitting light according to injected electrons and holes and changing a wavelength of the light depending on whether a biomaterial is absorbed by the light emitting layer; an electron injection layer injecting the electrons into the light emitting layer; and a hole injection layer injecting the holes into the light emitting layer.

In the above aspect of the present invention, when the biomaterial is absorbed by a side surface of the light emitting layer, a diameter of the light emitting layer may be increased, and a wavelength of the light may be changed. In addition, the light emitting layer may be made of silicon nitride (SiN).

In addition, the electron injection layer and the hole injection layer may be constructed with a silicon carbide based thin film, and the electron injection layer and the hole injection layer may have complementary polarities to each other.

In addition, the aforementioned silicon biosensor may further include a light detection unit recognizing existence and an amount of the biomaterial by analyzing a change of the wavelength of light, if necessary.

According to another aspect of the present invention, there is provided a silicon biosensor comprising: a self-emitting reaction unitemitting light according to injected electrons and holes and changing a wavelength of the light depending on whether a biomaterial is absorbed by the light emitting layer; and a light detection unit measuring a wavelength of light emitted from the self-emitting reaction unit and recognizing existence and an amount of a biomaterial by analyzing a change of the wavelength of light.

In the above aspect of the present invention, the self-emitting reaction unitmay comprise: a light emitting layer emitting light according to injected electrons and holes and changing a wavelength of the light depending on whether a biomaterial is absorbed by the light emitting layer; an electron injection layer injecting the electrons into the light emitting layer; and a hole injection layer injecting the holes into the light emitting layer.

In addition, when the biomaterial is absorbed by a side surface of the light emitting layer, a diameter of the light emitting layer may be increased, and a wavelength of the light may be changed. The light emitting layer may be made of silicon nitride (SiN).

In addition, the electron injection layer and the hole injection layer may be constructed with a silicon carbide based thin film, and the electron injection layer and the hole injection layer may have complementary polarities to each other.

According to another aspect of the present invention, there is provided a method of manufacturing a silicon biosensor, the method comprising: sequentially depositing a first type silicon film, silicon nano crystal, and a second type silicon film on an upper surface of a silicon substrate; forming a hole injection layer, a light emitting layer, and an electron injection layer by etching the first type silicon film, the silicon nano crystal, and the second type silicon film; forming a second type electrode on an upper surface of the electron injection layer; and forming a first type electron on both edges of the upper surface of the silicon substrate and under a central area of a lower surface of the silicon substrate.

In the above aspect of the present invention, the forming of the hole injection layer, the light emitting layer, and the electron injection layer may comprise: etching the first type silicon film, the silicon nano crystal, and the second type silicon film through a dry etching process; and forming the hole injection layer, the light emitting layer, and the electron injection layer by etching the first type silicon film and the second type silicon film through a wet etching process. Alternatively, in the forming of the hole injection layer, the light emitting layer, and the electron injection layer, the hole injection layer, the light emitting layer, and the electron injection layer which have the same diameter may be formed by concurrently etching the first type silicon film, the silicon nano crystal, and the second type silicon film through a dry etching process.

In addition, when the biomaterial is absorbed by a side surface of the light emitting layer, a diameter of the light emitting layer may be increased, and a wavelength of the light may be changed. The light emitting layer may be made of silicon nitride (SiN).

In addition, the electron injection layer and the hole injection layer may be constructed with a silicon carbide-based thin film, and the electron injection layer and the hole injection layer may have complementary polarities to each other.

### Advantageous Effects

In the silicon biosensor according to an embodiment of the present invention and the method of manufacturing the same, it is possible to reduce manufacturing costs of the biosensor and easily integrate or join the biosensor into silicon electronic elements by suggesting the self-emitting reaction unit which can be manufactured through a process of manufacturing a semiconductor device.

In addition, since the silicon biosensor according to an embodiment of the present invention concurrently performs an operation of a light source and an operation of a reaction unit through a self-emitting reaction unit, an additional light source is unnecessary. At this time, since the emitted light has an isotropic characteristic, it is possible to easily and optically construct the self-emitting reaction unit and a detection unit. Accordingly, an additional optical system is also unnecessary. That is, it is possible to produce low price biosensors in large quantities.

### BRIEF DESCRIPTION OF THE DRAWINGS

FIG. 1 illustrates a concept of an operation of a silicon biosensor according to an exemplary embodiment of the present invention;

FIG. 2 illustrates an operation of a self-emitting reaction unit according to an exemplary embodiment of the present invention in detail;

FIG. 3 illustrates a change in wavelength of light caused by an antigen-antibody reaction;

FIG. 4 illustrates a structure of a self-emitting reaction unit according to an exemplary embodiment of the present invention;

FIG. 5 illustrates procedures of manufacturing a self-emitting reaction unit according to an exemplary embodiment of the present invention; and

FIG. 6 is a flowchart of a procedure of detecting a biomaterial by using a silicon biosensor according to an exemplary embodiment of the present invention.

### BEST MODE FOR CARRYING OUT THE INVENTION

Exemplary embodiments of the present invention will now be described in detail with reference to the accompanying drawings. When it is determined that the detailed descriptions of the known techniques or structures related to the present invention depart from the scope of the invention, the detailed descriptions will be omitted.

Like reference numerals designates like elements throughout the specification.

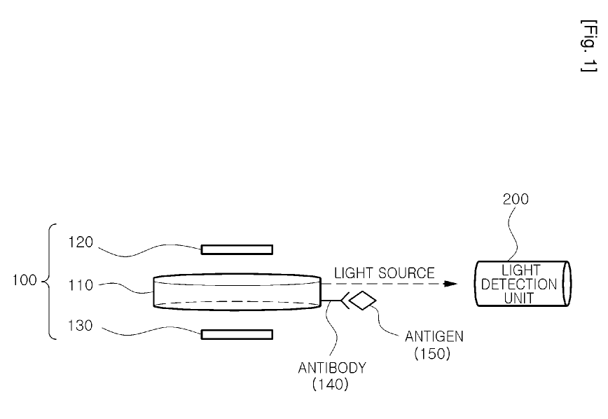

FIG. 1 illustrates a concept of an operation of a silicon biosensor according to an exemplary embodiment of the present invention.

Referring to FIG. 1, the silicon biosensor includes a self-emitting reaction unit 100 and a light detection unit 200. The self-emitting reaction unit 100 has a structure in which a light emitting layer 110 having a disk shape is inserted between an electron injection layer 120 and a hole injection layer 130.

At this time, the light emitting layer 110 emits light in response to electrons and holes which are injected through the electron injection layer 120 and the hole injection layer 130, respectively. If an antibody 140 and an antigen 150 react and combine with each other on a side of the light emitting layer 110, the light emitting layer 110 changes a wavelength of light.

Accordingly, the light detection unit 200 measures a wavelength of light emitted from the light emitting layer 110 before the antibody 140 and the antigen 150 reacts with each other and a wavelength of light emitted from the light emitting layer 10 after the antibody 140 and the antigen 150 reacts with each other, analyzes a difference between the wavelengths, and recognizes existence of the antigen 150 that is a desired biomaterial and an amount of the antigen 150.

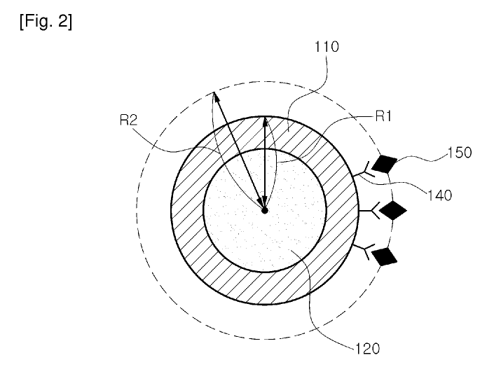

FIG. 2 is a top view illustrating a self-emitting reaction unit 100 according to an exemplary embodiment of the present invention so as to describe an operation of the self-emitting reaction unit 100 in detail.

Light emitted from the light emitting layer 110 is reflected from an interface between a side wall of the light emitting layer 110 and air due to a difference in dielectric constant between the light emitting layer 110 and air. At this time, the light is totally reflected from the interface between the side wall of the light emitting layer 110 and air.

The reflected light returns into the light emitting layer 110. The returning light is added to light emitted from the emitting layer 110 and amplified.

When the reflection and amplification processes are repeatedly performed, a light source using light emitted from the self-emitting reaction unit 100 has high efficiency of light emission.

When light is incident onto the side wall of the light emitting layer 110 within a critical angle, the light is emitted to the outside of the self-emitting reaction unit 100, that is, air.

At this time, a wavelength of the light emitted to the outside of the self-emitting reaction unit 100 depends on a diameter of the light emitting layer 110.

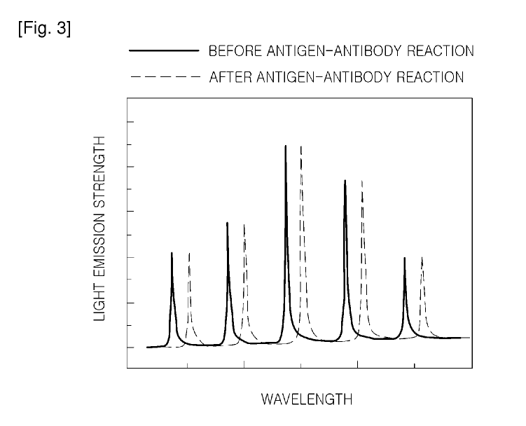

On the other hand, when the antibody 140 and the antigen 150 are absorbed by the side wall of the light emitting layer 110, as described above, the diameter of the light emitting layer 110 is increased. Accordingly, a radius R2 of the light emitting layer 110 after the antibody 140 and the antigen 150 are absorbed becomes greater than a radius R1 of an initial light emitting layer 110. As shown in FIG. 3, the wavelength of the light emitted from the light emitting layer 110 is also changed.

That is, referring to FIG. 3, the wavelength of light after the antibody 140 and the antigen 150 react with each other is greater than the wavelength of light before the antibody 140 and the antigen 150 react with each other.

Accordingly, the light detection unit 200 can analyze existence of the antigen 150 absorbed by the side wall of the light emitting layer 110, that is, the self-emitting reaction unit 100 and an amount of the antigen 150 by analyzing a variable wavelength of light.

In addition, since light emitted from the light emitting layer 110 has an isotropic characteristic, the existence and the amount of the antigen 150 may be measured along the side wall in any direction.

As a result, the silicon biosensor according to the embodiment may use the self-emitting reaction unit 100 including the light emitting layer 110 that emits light without an additional light source as a reaction unit in which the antibody 140 and the antigen 150 react with each other. In addition, since the existence and the amount of the antigen 150 may be easily measured through a general light detector 200 according to light with an isotropic characteristic, a complex optical system is not needed but a simple and low price biosensor may be constructed.

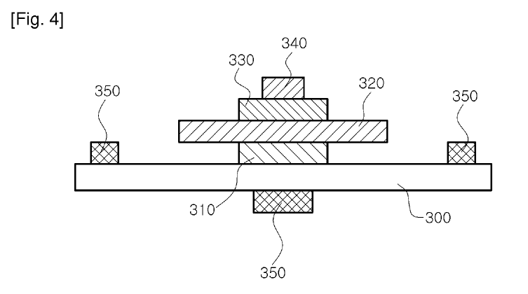

FIG. 4 is a cross sectional view illustrating a self-emitting reaction unit 100 according to an exemplary embodiment of the present invention so as to describe a structure of the self-emitting reaction unit 100.

Referring to FIG. 4, the self-emitting reaction unit 100 includes a hole injection layer 310 formed on a central area of an upper surface of a silicon substrate 300, a light emitting layer 320 formed on an upper surface of the injection layer 310, an electron injection layer 330 formed on a central area of an upper surface of the light emitting layer 320, an n-type electrode 340 formed on a central area of an upper surface of the electron injection layer 330, and a p-type electrode 350 formed on both edges of the upper surface of the silicon substrate 300 and formed under a central area of a lower surface of the silicon substrate 300.

Preferably, the hole injection layer 310 faces the light emitting layer 320. The electron injection layer 330 is located between the hole injection layer 310 and the light emitting layer 320.

The light emitting reaction unit 100, specifically, the light emitting layer 320 has a diameter equal to or less than 100 μm.

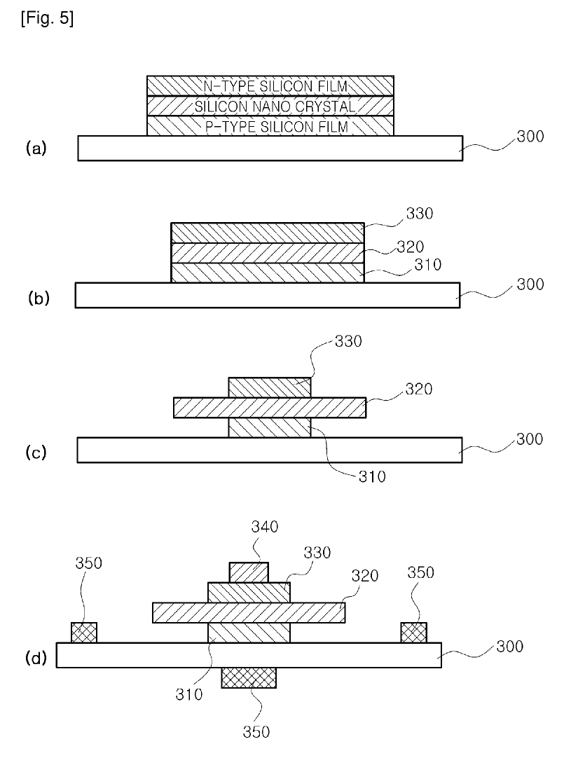

FIG. 5 illustrates procedures of manufacturing a self-emitting reaction unit 100 according to an exemplary embodiment of the present invention.

In the present invention, the self-emitting reaction unit 100 is embodied by using the silicon substrate 300. The silicon substrate 300 is advantageous for integration or joining with the silicon electronic elements. In addition, since the silicon substrate 300 is cheap and source gases for forming layers on the silicon substrate 300 are cheap, it is possible to manufacture the self-emitting reaction unit in low price.

As shown in (a) OF FIG. 5, a p-type silicon film, silicon nano crystal, and an n-type silicon film are sequentially deposited on an upper surface of the silicon substrate 300.

Preferably, a silicon carbide-based thin film such as a silicon carbide (SiC) thin film or a silicon carbon nitride (SiCN) film is used for the p and n type silicon films. Silicon nitride (SiN) is used for the silicon nano crystal.

As shown in (b) OF FIG. 5, the hole injection layer 310, the light emitting layer 320, and the electron injection layer 330 are formed by etching the p-type silicon film, the silicon nano crystal, and the n-type silicon film through a dry etching process.

As shown in (c) OF FIG. 5, the hole injection layer 310 and the electron injection layer 330 are etched again through a wet etching process so that the hole injection layer 310 and the electron injection layer 330 have a less diameter than the light emitting layer 320.

As shown in (d) OF FIG. 5, a current may be applied by forming the n-type electrode 340 on an upper surface of the electron injection layer 330 through a metal wiring process. Then, a current may be applied to the hole injection layer 310 through the silicon substrate 300 by forming the p-type electrode 350 on both edges of the upper surface of the silicon substrate 300 and under a central area of a lower surface of the silicon substrate 300.

At this time, the n and p type electrodes may be made of nickel (Ni), aluminum (Al), platinum (Pt), or gold (Au).

A current is applied to the hole injection layer 310 and the electron injection layer 330 through the n and p type electrodes 340 and 350, and holes and electrons are injected into the light emitting layer 320. Accordingly, the light emitting layer 320 emits light.

In the aforementioned description, the hole injection layer 310 and the electron injection layer 330 have diameters less than that of the light emitting layer 320. In some cases, the hole injection layer 310, the light emitting layer 320, and the electron injection layer 330 may have the same diameter.

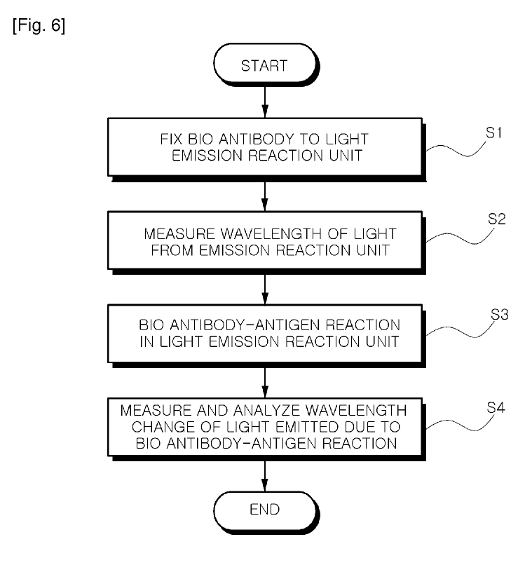

FIG. 6 is a flowchart of a procedure of detecting a biomaterial by using a silicon biosensor according to an exemplary embodiment of the present invention.

First, after the light emitting layer 320 emits light by applying a current to the self-emitting reaction unit 100, the antibody 140 is fixed to a side wall of the light emitting unit 320 in the self-emitting reaction unit 100 (S1), and a wavelength of light emitted from the light emitting unit 320 is measured (S2).

Then, after an antigen 150 is combined with the antibody 140 to cause a antibody-antigen reaction (S3), a wavelength of light emitted from the light emitting unit 320 is measured, again.

Then, existence and an amount of the antigen 150 absorbed by the self-emitting reaction unit 100 are recognized by comparing the wavelength of light measured in the step S2 with the wavelength of light measured in the step S4 and analyzing the comparison result.

While the present invention has been shown and described in connection with the exemplary embodiments, it will be apparent to those skilled in the art that modifications and variations can be made without departing from the spirit and scope of the invention as defined by the appended claims.

1. A silicon biosensor comprising:
a light emitting layer emitting light according to injected electrons and holes and changing a wavelength of the light depending on whether a biomaterial is absorbed by the light emitting layer;
an electron injection layer injecting the electrons into the light emitting layer; and
a hole injection layer injecting the holes into the light emitting layer.

2. The silicon biosensor of claim 1, wherein light emitting layer increases a diameter to change the wavelength of the light, when the biomaterial is absorbed by a side surface of the light emitting layer.

3. The silicon biosensor of claim 2, wherein the biomaterial is an antibody or antigen.

4. The silicon biosensor of claim 1, wherein the light emitting layer is made of silicon nitride (SiN).

5. The silicon biosensor of claim 1, wherein the electron injection layer and the hole injection layer are constructed with a silicon carbide based thin film, and the electron injection layer and the hole injection layer have complementary polarities to each other.

6. The silicon biosensor of claim 1, further comprising a light detection unit recognizing existence and an amount of the biomaterial by analyzing a change of the wavelength of light.

7. A silicon biosensor comprising:
a self-emitting reaction unitemitting light according to injected electrons and holes and changing a wavelength of the light depending on whether a biomaterial is absorbed by the light emitting layer; and
a light detection unit measuring a wavelength of light emitted from the self-emitting reaction unit and recognizing existence and an amount of a biomaterial by analyzing a change of the wavelength of light.

8. The silicon biosensor of claim 7, wherein the self-emitting reaction unit comprises:
a light emitting layer emitting light according to injected electrons and holes and changing a wavelength of the light depending on whether a biomaterial is absorbed by the light emitting layer;
an electron injection layer injecting the electrons into the light emitting layer; and
a hole injection layer injecting the holes into the light emitting layer.

9. The silicon biosensor of claim 8, wherein when the biomaterial is absorbed by a side surface of the light emitting layer, a diameter of the light emitting layer is increased, and a wavelength of the light is changed.

10. The silicon biosensor of claim 8, wherein the light emitting layer is made of silicon nitride (SiN).

11. The silicon biosensor of claim 8, wherein the electron injection layer and the hole injection layer are constructed with a silicon carbide based thin film, and the electron injection layer and the hole injection layer have complementary polarities to each other.

12. The silicon biosensor of claim 7, wherein the biomaterial is an antibody or antigen.

13. A method of manufacturing a silicon biosensor, the method comprising:
sequentially depositing a first type silicon film, silicon nano crystal, and a second type silicon film on an upper surface of a silicon substrate;
forming a hole injection layer, a light emitting layer, and an electron injection layer by etching the first type silicon film, the silicon nano crystal, and the second type silicon film;
forming a second type electrode on an upper surface of the electron injection layer; and
forming a first type electron on both edges of the upper surface of the silicon substrate and under a central area of a lower surface of the silicon substrate.

14. The method of claim 13, wherein the forming of the hole injection layer, the light emitting layer, and the electron injection layer comprises:
etching the first type silicon film, the silicon nano crystal, and the second type silicon film through a dry etching process; and
forming the hole injection layer, the light emitting layer, and the electron injection layer by etching the first type silicon film and the second type silicon film through a wet etching process.

15. The method of claim 13, wherein in the forming of the hole injection layer, the light emitting layer, and the electron injection layer, the hole injection layer, the light emitting layer, and the electron injection layer which have the same diameter are formed by concurrently etching the first type silicon film, the silicon nano crystal, and the second type silicon film through a dry etching process.

16. The method of claim 13, wherein the light emitting layer is made of silicon nitride (SiN).

17. The method of claim 13, wherein the electron injection layer and the hole injection layer are constructed with a silicon carbide-based thin film, and the electron injection layer and the hole injection layer have complementary polarities to each other.
